(19) United States
(12) Patent Application Publication
(10) Pub. No.: US 2026/0029716 A1
(43) Pub. Date: Jan. 29, 2026

(54) POLYMER COMPOUND FOR FORMING RESIST UNDERLAYER FILM, AND COMPOSITION FOR FORMING RESIST UNDERLAYER FILM COMPRISING SAME

(71) Applicant: DONGJIN SEMICHEM CO., LTD., Incheon (KR)

(72) Inventors: Dong Kyu JU, Hwaseong-si (KR); Hyun Jin KIM, Hwaseong-si (KR); Jung Youl LEE, Hwaseong-si (KR); Tae Ik KIM, Hwaseong-si (KR); Chang Sik CHOI, Hwaseong-si (KR)

(21) Appl. No.: 19/225,472

(22) Filed: Jun. 2, 2025

Related U.S. Application Data
(63) Continuation of application No. PCT/KR2023/019681, filed on Dec. 1, 2023.

(30) Foreign Application Priority Data
Dec. 15, 2022 (KR) 10-2022-0176125

(51) Int. Cl. G03F 7/09; C08F 20/30

(52) U.S. Cl. CPC G03F 7/094; C08F 20/30; C08F 2810/20

(57) ABSTRACT

A polymer compound for forming a resist underlayer film can lower the optimal exposure amount of a resist film without affecting the shape of the resist pattern film after development. The polymer compound for forming a resist underlayer film includes a repeating unit represented by the following formula:

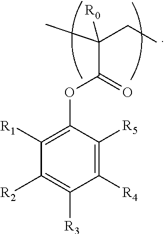

### CROSS-REFERENCE TO RELATED APPLICATIONS

This application is a Continuation of International Application No. PCT/KR2023/019681 filed Dec. 1, 2023, which claims priority from Korean Application No. 10-2022-0176125 filed Dec. 15, 2022. The aforementioned applications are incorporated herein by reference in their entireties.

### TECHNICAL FIELD

The present disclosure relates to a polymer compound for forming a resist underlayer film, and a composition for forming a resist underlayer film including the same.

### RELATED ART

EUV (extreme ultraviolet) lithography is a technology that forms finer-sized patterns for high integration of semiconductor chips. The biggest difference between the EUV lithography and existing ArF imm (immersion argon fluoride), ArF (argon fluoride) and KrF (krypton fluoride) lithography is that the EUV lithography uses light having a wavelength of about 13.5 nm. As the wavelength of light used becomes shorter, light penetrates most elements due to the high energy of photons, and the need for a lower anti-reflection film that has been used in an existing process disappears. However, in a process for mass producing most resist films for EUV, adhesion with a resist underlayer film at a required level is not secured, and therefore, studies for improving adhesion without the anti-reflection function have been continuously conducted.

In addition, an economic aspect of the EUV lithography caused by enormous equipment price and maintenance cost is one of the challenges to overcome. For a general resist film, the amount of light irradiated for forming a desired pattern is fixed, and this is referred to as an optimal exposure amount.

A number of studies are in progress to minimize an exposure amount of an EUV resist film, however, when simply reducing the exposure amount, there is a problem of reducing surface roughness and size uniformity of a resist pattern film. When the surface roughness and the size uniformity of the resist pattern film are reduced, product performance declines, leading to a decrease in the product yield. This phenomenon is referred to as a stochastic effect. Meanwhile, the energy of photons having a wavelength of 13.5 nm is about 92 eV in an EUV process, which is 18.4 times higher than the energy of photons used in existing KrF lithography of about 5 eV. Accordingly, the number of photons irradiated at the same exposure amount significantly decreases in an EUV process compared to an existing process, which further highlights the stochastic effect, and as a result, studies to resolve this issue have been continuously conducted.

### SUMMARY

The present disclosure is directed to providing a polymer compound for forming a resist underlayer film capable of lowering an optimal exposure amount of a resist film without affecting the shape of the resist pattern film after development.

The present disclosure is also directed to providing a composition for forming a resist underlayer film, the composition including the polymer compound for forming a resist underlayer film.

Objects of the present disclosure are not limited to the above-mentioned objects, and other objects and advantages of the present disclosure not mentioned will be understood by the following description, and more clearly understood by embodiments of the present disclosure. In addition, it may be readily understood that objects and advantages of the present disclosure may be embodied by means described in the claims and combinations thereof.

According to a first aspect of the present disclosure to achieve the above-described objects, there is provided a polymer compound for forming a resist underlayer film, the compound including a repeating unit represented by the following General Formula 1.

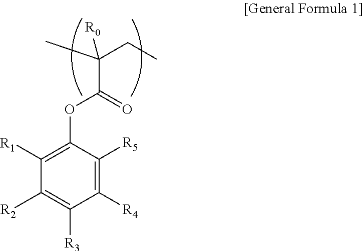

Specifically, in General Formula 1, R₀ is a hydrogen atom, or a linear or branched alkyl group having 1 to 4 carbon atoms. R₁, R₂, R₃, R₄ and R₅ are each independently a hydrogen atom, a linear or branched alkyl group having 1 to 6 carbon atoms, a halogen atom, or a hydroxyl group, and at least one of R₁, R₂, R₃, R₄ and R₅ is a halogen atom and at least another one is a hydroxyl group.

According to a second aspect of the present disclosure, four selected from among R₁, R₂, R₃, R₄ and R₅ may include a halogen atom, and specifically, may be formed with a halogen atom.

According to a third aspect of the present disclosure, the halogen atom may be a fluorine atom or an iodine atom.

According to a fourth aspect of the present disclosure, the polymer compound for forming a resist underlayer film may further include a repeating unit derived from an unsaturated compound containing at least one crosslinking reaction functional group at one end.

According to a fifth aspect of the present disclosure, the crosslinking reaction functional group may be a hydroxyl group or a thiol group.

According to a sixth aspect of the present disclosure, the unsaturated compound may be an acryl-based compound.

According to a seventh aspect of the present disclosure, the polymer compound for forming a resist underlayer film may further include a repeating unit represented by the following General Formula 2.

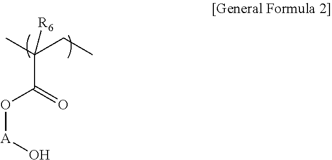

In General Formula 2, R₆ is a hydrogen atom, or a linear or branched alkyl group having 1 to 4 carbon atoms. A is a substituted or unsubstituted chain-type saturated hydrocarbon linking group having 2 to 12 carbon atoms, a substituted or unsubstituted chain-type unsaturated hydrocarbon linking group having 3 to 12 carbon atoms including at least one unsaturated bond, or a substituted or unsubstituted cyclic linking group having 3 to 12 carbon atoms.

According to an eighth aspect of the present disclosure, the repeating unit represented by General Formula 1 and the repeating unit represented by General Formula 2 may have a molar ratio (General Formula 1:General Formula 2) of 50:50 or greater and 100:0 or less.

According to a ninth aspect of the present disclosure, the hydroxyl group and the halogen atom may have a ratio (hydroxyl group:halogen atom) of 1:1 to 1:4 in General Formula 1.

According to a tenth aspect of the present disclosure, there is provided a composition for forming a resist underlayer film, and the composition may include the polymer compound for forming a resist underlayer film according to any one of the first to ninth aspects; and a solvent.

According to an eleventh aspect of the present disclosure, a content of the polymer compound for forming a resist underlayer film may be from 0.02% by weight to 1.00% by weight based on a total weight of the composition for forming a resist underlayer film.

According to a twelfth aspect of the present disclosure, the composition for forming a resist underlayer film may further include at least one of a crosslinking agent or a thermal acid generator.

The technical solutions do not list all the features of the present disclosure. Various features of the present disclosure and corresponding advantages and effects will be understood in more detail with reference to specific embodiments described below.

According to an aspect of the present disclosure, a polymer compound for forming a resist underlayer film capable of maintaining the same roughness and size of a resist pattern film even at an exposure amount lower than an optimal exposure amount of the resist film due to the effect of secondary electrons generated by increasing a photon absorption rate of the resist underlayer film can be provided.

Specific effects of the present disclosure in addition to the above-described effects will be described together while describing specific details for carrying out the disclosure hereinafter.

### DETAILED DESCRIPTION

In the present specification, singular forms include plural forms as well, unless the context clearly indicates otherwise.

When multiple embodiments are described in the present specification, effects of the present disclosure may be defined to include not only the working effects obtained from each embodiment itself, but also the effects obtained from a relevant combination of each embodiment. For example, even when embodiments 1 and 2 are each independently described in the present specification, the effects obtained from a combination of the embodiments 1 and 2 may also be included in the effects of the present disclosure, unless the context clearly indicates otherwise.

In the present specification, a term such as “about” or “substantially” means a reasonable amount of variation of a term modified so as not to significantly change a final result. Such a term may be interpreted to include a variation of at least ±5% or at least ±10% within a limit that the variation does not invalidate the meaning of the word by the modification.

In the present specification, a numerical range indicated by using a term “to” represents a numerical range including values described before and after the term respectively as a lower limit value and an upper limit value. When numerical values as upper and lower limits of any numerical range are each disclosed as multiple values, the numerical range disclosed in the present specification may be understood as any numerical range having any one of the multiple lower limit values and any one of the multiple upper limit values respectively as a lower limit value and an upper limit value. For example, it may be understood that a to b, or c to d described in the present specification is described as a or greater and b or less, a or greater and d or less, c or greater and d or less, or c or greater and b or less.

In the present specification, “including at least one of a, b or c” may include a, b or c alone, or may include a combination of two or more selected from the group consisting of a b and c.

In the present specification, a term “substituted” may be defined as at least one hydrogen atom being replaced by any one selected from the group consisting of a halogen atom, a hydroxyl group, a carboxyl group, a nitro group, an amine group, a sulfide group, a thiol group, an alkoxy group, an acetoxy group, a nitrile group, an aldehyde group, an ether group, an ester group, an acetal group, a ketone group, an alkyl group, an alkenyl group, an alkynyl group, a cycloalkyl group, a heterocycloalkyl group, an allyl group, an aryl group, a heteroaryl group, derivatives thereof and any combinations thereof.

In the present specification, a “layer” or film may include a case in which, when observing an area on which the corresponding layer or film is present, the layer or film is formed on only a portion of the corresponding area in addition to the case in which the layer or film is formed over the entire corresponding area. For example, the surface of the layer or film may be defined to have a flat shape, a non-flat shape and a combination thereof; or a continuous shape, a discontinuous shape and a combination thereof. For example, when another member is formed as a layer or film directly on one member, coverage of the another member with respect to the surface of the one member may be defined as 1% or greater, 5% or greater, 10% or greater, 20% or greater, 30% or greater, 40% or greater, 50% or greater, 60% or greater, 70% or greater, 80% or greater, 85% or greater, 90% or greater, 95% or greater or 99% or greater.

In the present specification, a “weight average molecular weight” or “number average molecular weight” is a standard polystyrene-converted molecular weight and may be analyzed through a GPC (gel permeation chromatography) device. Herein, in the GPC analysis method, tetrahydrofuran may be used as a developing solvent, and the GPC analysis may be conducted under an analysis condition of a sample concentration of 5 mg/mL, a sample supply amount of 100 μl, a temperature of 40° C. and a flow rate of 1 mL/min.

According to an aspect of the present disclosure, there is provided a polymer compound for forming a resist underlayer film, the compound including a repeating unit represented by the following General Formula 1.

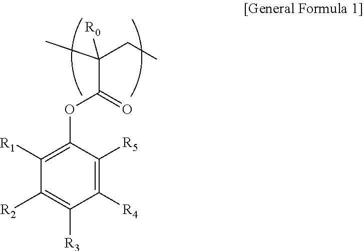

Specifically, in General Formula 1, R₀ is a hydrogen atom or a linear or branched alkyl group having 1 to 4 carbon atoms. R₁, R₂, R₃, R₄ and R₅ are each independently a hydrogen atom, a linear or branched alkyl group having 1 to 6 carbon atoms, a halogen atom, or a hydroxyl group. At least one of R₁, R₂, R₃, R₄ and R₅ is a halogen atom, and at least another one is a hydroxyl group.

A resist underlayer film is basically introduced to improve adhesion of a resist, and an optimal exposure amount irradiated to form a desired resist pattern may vary depending on the formation of the resist underlayer film. For example, simply reducing an exposure amount for a resist film causes a problem of reducing surface roughness and size uniformity of the resist pattern film. According to one aspect of the present disclosure, at least one of R₁, R₂, R₃, R₄ and R₅ is a halogen atom and another one includes a hydroxyl group in the repeating unit represented by General Formula 1, and therefore, EUV photon absorption of the resist underlayer film is facilitated by the halogen atom, increasing generation of secondary electrons, and then the generated secondary electrons may be smoothly transferred to an upper resist film through the hydroxyl group. Even when the repeating unit of General Formula 1 is substituted with a hydroxyl group, generation of secondary electrons may not sufficiently increase when the repeating unit of General Formula 1 is not substituted with a halogen atom, and this may cause a problem in that an optimal exposure amount of the resist film may not be sufficiently reduced. Even when the repeating unit represented by General Formula 1 is substituted with a halogen atom, secondary electrons generated by the halogen atom may not be smoothly transferred to an upper resist film when the repeating unit represented by General Formula 1 is not substituted with a hydroxyl group, and an optimal exposure amount of the resist film may become worse instead of being improved. In other words, according to one aspect of the present disclosure, when substituents of the repeating unit represented by General Formula 1 are formed with a combination of a hydroxyl group and a halogen atom, a polymer compound for forming a resist underlayer film capable of maintaining the same roughness and size of a resist pattern film even at an exposure amount lower than an optimal exposure amount of the resist film may be provided due to the effect of secondary electrons generated by increasing a photon absorption rate of the resist underlayer film.

Hereinafter, constitutions of the present disclosure will be described in more detail.

### 1. Polymer Compound for Forming Resist Underlayer Film

The polymer compound for forming a resist underlayer film according to the present disclosure includes a repeating unit represented by the following General Formula 1.

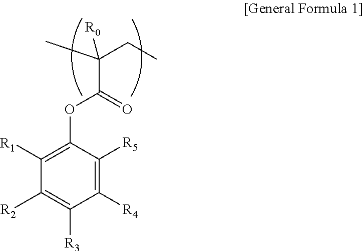

Specifically, in General Formula 1, R₀ may be a hydrogen atom or a linear or branched alkyl group having 1 to 4 carbon atoms, specifically a hydrogen atom or a linear or branched alkyl group having 1 to 3 carbon atoms, and more specifically a hydrogen atom or an alkyl group having 1 to 2 carbon atoms. When the number of carbon atoms of R₀ in General Formula 1 satisfies the above-mentioned numerical range, an advantage of readily increasing a molar concentration of the repeating unit represented by General Formula 1 may be provided in a process for synthesizing the polymer compound.

Specifically, in General Formula 1, R₁, R₂, R₃, R₄ and R₅ are each independently a hydrogen atom, a linear or branched alkyl group having 1 to 6 carbon atoms, a halogen atom, or a hydroxyl group. At least one of R₁, R₂, R₃, R₄ and R₅ is a halogen atom and at least another one is a hydroxyl group. In the repeating unit represented by General Formula 1, when at least one of R₁, R₂, R₃, R₄ and R₅ is a halogen atom and another one is a hydroxyl group, EUV photon absorption of the resist underlayer film is facilitated by the halogen atom, increasing generation of secondary electrons, and then the generated secondary electrons may be smoothly transferred to an upper resist film through the hydroxyl group. Even when the repeating unit of General Formula 1 is substituted with a hydroxyl group, generation of secondary electrons may not sufficiently increase when the repeating unit of General Formula 1 is not substituted with a halogen atom, and an optimal exposure amount of the resist film may not be sufficiently reduced. Even when the repeating unit represented by General Formula 1 is substituted with a halogen atom, secondary electrons generated by the halogen atom may not be smoothly transferred to an upper resist film when the repeating unit represented by General Formula 1 is not substituted with a hydroxyl group, and an optimal exposure amount of the resist film may become worse instead of being improved.

According to an embodiment of the present disclosure, the number of halogen atoms in R₁, R₂, R₃, R₄ and R₅ may be 4. When the number of halogen atoms in R₁, R₂, R₃, R₄ and R₅ is 4, EUV photon absorption of the resist underlayer film is further facilitated, increasing generation of secondary electrons. Accordingly, an optimal exposure amount of the resist film may be sufficiently reduced.

According to an embodiment of the present disclosure, the halogen atom may be a fluorine atom or an iodine atom, and specifically an iodine atom. According to an embodiment of the present disclosure, generation of etching gas may be effectively prevented when the halogen atom is a fluorine atom or an iodine atom compared to other halogen atoms. Meanwhile, an iodine atom has high absorbance for an EUV light source, and therefore, may further reduce an optimal exposure amount of the resist film compared to a fluorine atom.

According to another embodiment of the present disclosure, the polymer compound for forming a resist underlayer film may further include a repeating unit derived from an unsaturated compound containing at least one crosslinking reaction functional group at one end. Specifically, the crosslinking reaction functional group may be a highly reactive functional group inducing a chemical bond with a crosslinking agent. The unsaturated compound may be a compound including an unsaturated bond such as a carbon-carbon double bond (C═C). Specifically, the unsaturated compound contains at least one crosslinking reaction functional group at one end, thereby increasing the degree of crosslinking when forming the resist underlayer film, and as a result, a phenomenon of resist pattern collapse may be alleviated during the process for forming a pattern such as line and space.

Specifically, the crosslinking reaction functional group may be a hydroxyl group or a thiol group, and more specifically a hydroxyl group.

Specifically, the unsaturated compound may be an acryl-based compound. For example, the acryl-based compound may be hydroxyethyl methacrylate, 4-hydroxyphenyl methacrylate, 3-hydroxyadamantan-1-yl methacrylate or the like without being particularly limited.

According to another embodiment of the present disclosure, the polymer compound for forming a resist underlayer film may further include a repeating unit represented by the following General Formula 2.

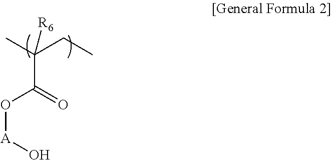

In General Formula 2, R₆ may be a hydrogen atom, or a linear or branched alkyl group having 1 to 4 carbon atoms, specifically a linear or branched alkyl group having 1 to 3 carbon atoms and more specifically an alkyl group having 1 to 2 carbon atoms. When the number of carbon atoms of R₆ satisfies the above-mentioned numerical range, the molar concentration of the repeating unit represented by General Formula 2 may be readily adjusted in a process for synthesizing the polymer.

In General Formula 2, A may be a substituted or unsubstituted chain-type saturated hydrocarbon linking group having 2 to 12 carbon atoms, a substituted or unsubstituted chain-type unsaturated hydrocarbon linking group having 3 to 12 carbon atoms including at least one unsaturated bond, or a substituted or unsubstituted cyclic linking group having 3 to 12 carbon atoms. Specifically, the chain-type saturated hydrocarbon linking group may be a chain-type linking group formed with a carbon-carbon single bond, and for example, may be —CH₂—CH₂—, —CH₂—CH₂—CH₂— or the like. The chain-type unsaturated hydrocarbon linking group may be a linking group including at least one of carbon-carbon double bond and triple bond, and for example, may be —HC═CH—CH₂— or the like. The cyclic linking group may be a linking group including at least one of an aliphatic ring and an aromatic ring, and for example, may be a benzene ring linking group or a polycyclic linking group. In addition, the meaning of ‘substituted’ in the present specification may be defined as at least one hydrogen atom being substituted with a heteroatom or a functional group containing a heteroatom. For example, the functional group containing a heteroatom may be a hydroxyl group, an amine group, an ester group, an ether group, an alkoxy group, a thiol group, a ketone group or the like.

According to another embodiment of the present disclosure, the polymer compound for forming a resist underlayer film may be formed with the repeating unit represented by General Formula 1. By the polymer compound for forming a resist underlayer film being formed with the repeating unit represented by General Formula 1, an optimal exposure amount of the resist film may be further reduced without affecting a pattern shape of the resist film.

According to another embodiment of the present disclosure, the repeating unit represented by General Formula 1 and the repeating unit represented by General Formula 2 may have a molar ratio (General Formula 1:General Formula 2) of 50:50 or greater and 100:0 or less or 50:50 or greater and less than 100:0, and specifically, 80:20 or greater and 100:0 or less or 80:20 or greater and less than 100:0. When the repeating unit represented by General Formula 1 and the repeating unit represented by General Formula 2 have a molar ratio of 100:0, the polymer compound according to the present disclosure is a compound formed only with the repeating unit represented by General Formula 1. When the molar ratio between the repeating unit represented by General Formula 1 and the repeating unit represented by General Formula 2 satisfies the above-mentioned molar ratio range or the polymer compound according to the present disclosure is formed only with the repeating unit represented by General Formula 1, an optimal exposure amount of a resist film may be further reduced without affecting a pattern shape of the resist film. The molar ratio between the repeating units represented by General Formulae 1 and 2 may be analyzed through, for example, ¹H-NMR.

According to another embodiment of the present disclosure, the hydroxyl group and the halogen atom in General Formula 1 may have a ratio (hydroxyl group:halogen atom) of 1:1 to 1:4, and specifically 1:2 to 1:4. When the ratio between the hydroxyl group and the halogen atom in General Formula 1 satisfies the above-mentioned numerical range, an optimal exposure amount of a resist film may be further reduced without affecting a pattern shape of the resist film. The ratio between the hydroxyl group and the halogen atom in General Formula 1 may be analyzed through, for example, NMR or an elemental content analysis method.

The polymer compound for forming a resist underlayer film according to the present disclosure may have a weight average molecular weight (M_{W}) of 1,500 g/mol to 50,000 g/mol, and specifically 3,000 g/mol to 10,000 g/mol. When the weight average molecular weight of the polymer compound for forming a resist underlayer film satisfies the above-mentioned numerical range, the manufactured resist underlayer film may not be partially dissolved by the solvent in the resist composition and at the same time, may have an appropriate level of solubility for the solvent in the resist underlayer film composition, and the resist underlayer film may have an appropriate level of etching rate in a dry etching process.

### 2. Composition for Forming Resist Underlayer Film

Another embodiment of the present disclosure provides a composition for forming a resist underlayer film, the composition including: the polymer compound for forming a resist underlayer film according to the present disclosure; and a solvent. The description repeated with the part described above will be briefly described or not be included.

The content of the polymer compound for forming a resist underlayer film according to the present disclosure may be from 0.02% by weight to 1.00% by weight, and specifically from 0.02% by weight to 0.50% by weight based on the total weight of the composition for forming a resist underlayer film. When the content of the polymer compound for forming a resist underlayer film satisfies the above-mentioned numerical range, the resist underlayer film may be readily formed, and a resist underlayer film having an appropriate thickness may be obtained, accomplishing sufficient transfer of an upper resist film shape.

The solvent according to the present disclosure may be an organic solvent commonly used in a composition for forming a resist underlayer film. For example, the organic solvent may be any one selected from the group consisting of cyclohexanone, cyclopentanone, butyrolactone, dimethylacetamide, dimethylformamide, dimethyl sulfoxide, N-methyl pyrrolidone (NMP), tetrahydrofurfural alcohol, propylene glycol monomethyl ether (PGME), propylene glycol monomethyl ether acetate (PGMEA), ethyl lactate, methyl 2-hydroxyisobutyrate (HBM) and mixtures thereof. According to an embodiment, the content of the organic solvent may be, based on the total weight of the composition for forming a resist underlayer film, the remainder excluding the polymer compound for forming a resist underlayer film, a crosslinking agent, and a thermal acid generator to be described later; or the remainder excluding the polymer compound for forming a resist underlayer film, a crosslinking agent, a thermal acid generator, and an additive.

The composition for forming a resist underlayer film according to the present disclosure may further include at least one of a crosslinking agent or a thermal acid generator.

The crosslinking agent according to the present disclosure may facilitate a crosslinking reaction between the polymer compounds for forming a resist underlayer film. Specifically, the content of the crosslinking agent may be from 0.005% by weight to 1.0% by weight, and more specifically from 0.02% by weight to 0.10% by weight with respect to the total weight of the composition for forming a resist underlayer film. When the content of the crosslinking agent satisfies the above-mentioned numerical range, the resist underlayer film may be readily formed. For example, the crosslinking agent may correspond to one selected from the group consisting of a melamine series crosslinking agent having a crosslinkage-forming substituent such as a methylol group or a methoxymethyl group, an epoxy series crosslinking agent and combinations thereof, and generally, MX-270, MX-279, MX-280, MW-390 and the like of Sanwa Chemical Co., Ltd. may be used. The melamine series crosslinking agent may correspond to one selected from the group consisting of hexamethylol melamine, hexamethoxymethyl melamine, compounds in which 1 to 5 of methylol groups of hexamethylol melamine are methoxymethylated, hexamethoxyethyl melamine, hexaacyloxymethyl melamine, and compounds in which 1 to 5 of methylol groups of hexamethylol melamine are acyloxymethylated. The epoxy series crosslinking agent may correspond to a material having an epoxy group and having crosslinking properties. For example, the epoxy series crosslinking agent may include at least one selected from the group consisting of divalent glycidyl group-containing low molecular weight compounds such as bisphenol A glycidyl ether, ethylene glycol diglycidyl ether, butanediol diglycidyl ether, hexanediol diglycidyl ether, dihydroxybiphenyl diglycidyl ether, phthalic acid diglycidyl ester, and N,N-diglycidyl aniline; trivalent glycidyl group-containing low molecular weight compounds represented by trimethylolpropane triglycidyl ether, trimethylolphenol triglycidyl ether, and trisP-PA triglycidyl ether; tetravalent glycidyl group-containing low molecular weight compounds represented by pentaerythritol tetraglycidyl ether and tetramethylolbisphenol A tetraglycidyl ether; polyvalent glycidyl group-containing low molecular weight compounds such as dipentaerythritol pentaglycidyl ether and dipentaerythritol hexaglycidyl ether; and glycidyl group-containing high molecular weight compounds represented by polyglycidyl (meth)acrylate and an 1,2-epoxy-4-(2-oxiranyl)cyclohexane adduct of 2,2-bis(hydroxymethyl)-1-butanol.

The thermal acid generator according to the present disclosure may facilitate a crosslinking reaction of the polymer compound for forming a resist underlayer film. As the thermal acid generator, common thermal acid generators facilitating a crosslinking reaction may be used, and one selected from the group consisting of ammonium salt-based compounds, sulfonium salt-based compounds, iodonium salt-based compounds, and mixtures thereof may be used. As the thermal acid generator, for example, triethylammonium nonaflate, triphenylsulfonium nonaflate, dodecyl benzenesulfonic acid, para-toluene sulfonic acid, and the like may be used. Specifically, the content of the thermal acid generator may be from 0.001% by weight to 0.5% by weight, and more specifically from 0.005% by weight to 0.10% by weight based on the total weight of the composition for forming a resist underlayer film. When the content of the thermal acid generator satisfies the above-mentioned numerical range, the resist film may be readily formed and at the same time, generation of fume may be prevented during a heating process.

The composition for forming a resist underlayer film according to the present disclosure may further include an additive as necessary. Specifically, the additive may be one selected from the group consisting of an adhesion aid, a surfactant, a rheology modifier, and mixtures thereof. The content of the additive may be appropriately modified.

The adhesion aid may be added for the purpose of improving adhesion of the resist underlayer film to a substrate or a resist film, and particularly preventing the resist film from being peeled off during development. Examples of the adhesion aid may include chlorosilanes such as trimethylchlorosilane, dimethylvinylchlorosilane, methyldiphenylchlorosilane and chloromethyldimethylchlorosilane; alkoxysilanes such as trimethylmethoxysilane, dimethyldiethoxysilane, methyldimethoxysilane, dimethylvinylethoxysilane, diphenyldimethoxysilane and phenyltriethoxysilane; silazanes such as hexamethyldisilazane, N,N′-bis(trimethylsilyl)urea, dimethyltrimethylsilylamine and trimethylsilylimidazole; silanes such as vinyltrichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; or urea such as 1,1-dimethylurea and 1,3-dimethylurea, or thiourea compounds.

The surfactant may be added to prevent pinholes or striation from occurring and to further improve coatability for surface stains. For example, as the surfactant, at least one selected from the group consisting of non-ionic surfactants such as polyoxyethylene alkyl ethers represented by polyoxyethylene lauryl ether, polyoxyethylene stearyl ether, polyoxyethylene cetyl ether, and polyoxyethylene oleyl ether; polyoxyethylene alkylaryl ethers represented by polyoxyethylene octylphenol ether and polyoxyethylene nonylphenol ether; polyoxyethylene polyoxypropylene block copolymers; sorbitan fatty acid esters represented by sorbitan monolaurate, sorbitan monopalmitate, sorbitan monostearate, sorbitan monooleate, sorbitan trioleate, and sorbitan tristearate; and polyoxyethylene sorbitan fatty acid esters represented by polyoxyethylene sorbitan monolaurate, polyoxyethylene sorbitan monopalmitate, polyoxyethylene sorbitan monostearate, polyoxyethylene sorbitan triolate and polyoxyethylene sorbitan tristearate, fluorine-based surfactants represented by EFTOP EF301, EF303, and EF352 (manufactured by Tohkem Products Corporation), MEGAFAC F171 and F173 (manufactured by Dainippon Ink and Chemicals, Inc.), FLUORAD FC430 and FC431 (manufactured by Sumitomo 3M Limited.), ASAHI GUARD AG710, SURFLON S-382, SC101, SC102, SC103, SC104, SC105, and SC106 (manufactured by Asahi Glass Co., Ltd.), and organosiloxane polymer KP341 (manufactured by Shin-Etsu Chemical Co., Ltd.) may be used.

The rheology modifier may be added for the purpose of improving fluidity of the resist underlayer film composition. Examples of the rheology modifier may include phthalic acid derivatives such as dimethyl phthalate, diethyl phthalate, diisobutyl phthalate, dihexyl phthalate, and butylisodecyl phthalate; adipic acid derivatives such as di-normal butyl adipate, diisobutyl adipate, diisooctyl adipate, and octyl decyl adipate; maleic acid derivatives such as di-normal butyl maleate, diethyl maleate, and dinonyl maleate; oleic acid derivatives such as methyl oleate, butyl oleate, and tetrahydrofurfuryl oleate; or stearic acid derivatives such as normal butyl stearate and glyceryl stearate.

The resist underlayer film according to the present disclosure is obtained by curing the composition for forming a resist underlayer film.

A method for manufacturing the resist underlayer film according to the present disclosure may include: coating the composition for forming a resist underlayer film on an upper portion of a layer to be etched such as a silicon wafer or an aluminum substrate; and crosslinking the coated composition.

For example, the coating of the composition for forming a resist underlayer film may be performed using common methods such as spin coating, roller coating, and a spray method, and the crosslinking of the coated composition for forming a resist underlayer film may be performed by heating the coated composition in a device such as a high-temperature plate or a convection oven. For example, the crosslinking may be performed at 90° C. to 240° C. When the temperature satisfies the above-mentioned temperature range, the solvent is sufficiently removed, and the crosslinking reaction may be sufficiently achieved.

Hereinafter, examples of the present disclosure will be described in detail so that those skilled in the art to which the present disclosure pertains may readily carry out the present disclosure. However, these are for illustrative purposes only, and the scope of the present disclosure is not limited by the following description.

### Synthesis Example: Synthesis of Polymer Compound for Forming Resist Underlayer Film

### Example 1: Synthesis Example of Compound Represented by Chemical Formula 1

2-Butanone (40 g) was introduced to a 250 mL reactor, and after raising the temperature to 85° C., 3-fluoro-4-hydroxyphenyl methacrylate (17.15 g), hydroxyethyl methacrylate (2.85 g), and dimethyl 2,2′-azobis(2-methylpropionate) (2.01 g) were added dropwise to the 2-butanone (40 g) solution over 6 hours. After refluxing the mixture for 12 hours, the temperature was lowered to room temperature to finish the polymerization reaction. The 2-butanone was evaporated using a rotary evaporator, and then ethyl acetate (40 g) was added thereto. Deionized water (40 g) was introduced thereto, and the result was stirred and then allowed to stand to separate the layers. After removing the lower aqueous layer, deionized water (40 g) was introduced again thereto, and the result was stirred and then allowed to stand to separate the layers. After removing the lower aqueous layer, the solvent was removed using a rotary evaporator, and the solvent-removed result was dissolved in tetrahydrofuran (180 g). The solution prepared as above was added dropwise to heptane (2 kg), and the formed precipitate was filtered to synthesize a compound represented by the following Chemical Formula 1.

As identified through 1H-NMR, the molar ratio (m:n) between respective repeating units in the compound represented by the following Chemical Formula 1 was 80:20.

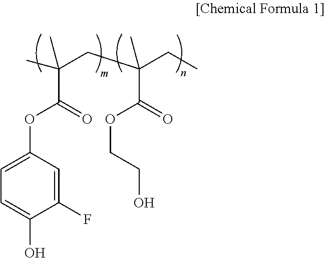

### Example 2: Synthesis Example of Compound Represented by Chemical Formula 2

A compound represented by the following Chemical Formula 2 was synthesized in the same manner as in Example 1, except that 3-fluoro-5-hydroxyphenyl methacrylate (17.15 g) was used instead of 3-fluoro-4-hydroxyphenyl methacrylate (17.15 g).

As identified through ¹H-NMR, the molar ratio (m:n) between respective repeating units in the compound represented by the following Chemical Formula 2 was 80:20.

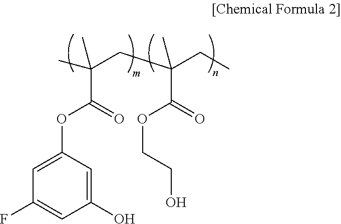

### Example 3: Synthesis Example of Compound Represented by Chemical Formula 3

A compound represented by the following Chemical Formula 3 was synthesized in the same manner as in Example 1, except that 3-fluoro-2-hydroxyphenyl methacrylate (17.15 g) was used instead of 3-fluoro-4-hydroxyphenyl methacrylate (17.15 g).

As identified through 1H-NMR, the molar ratio (m:n) between respective repeating units in the compound represented by the following Chemical Formula 3 was 80:20.

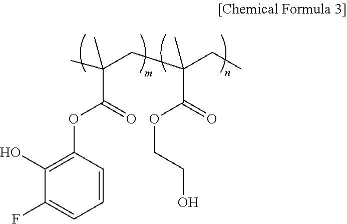

### Example 4: Synthesis Example of Compound Represented by Chemical Formula 4

A compound represented by the following Chemical Formula 4 was synthesized in the same manner as in Example 1, except that 3-hydroxy-2-iodophenyl methacrylate (18.07 g) was used instead of 3-fluoro-4-hydroxyphenyl methacrylate (17.15 g), hydroxyethyl methacrylate was used in an amount of 1.93 g instead of 2.85 g, and dimethyl 2,2′-azobis(2-methylpropionate) was used in an amount of 1.37 g instead of 2.01 g.

As identified through ¹H-NMR, the molar ratio (m:n) between respective repeating units in the compound represented by the following Chemical Formula 4 was 80:20.

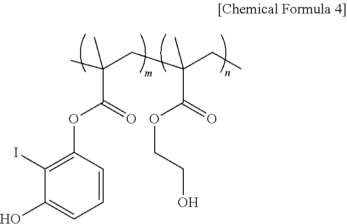

### Example 5: Synthesis Example of Compound Represented by Chemical Formula 5

A compound represented by the following Chemical Formula 5 was synthesized in the same manner as in Example 1, except that 2,3,5,6-tetrafluoro-4-hydroxyphenyl methacrylate (13.16 g) was used instead of 3-fluoro-4-hydroxyphenyl methacrylate (17.15 g), hydroxyethyl methacrylate was used in an amount of 6.84 g instead of 2.85 g, and dimethyl 2,2′-azobis(2-methylpropionate) was used in an amount of 1.94 g instead of 2.01 g.

As identified through ¹H-NMR, the molar ratio (m:n) between respective repeating units in the compound represented by the following Chemical Formula 5 was 50:50.

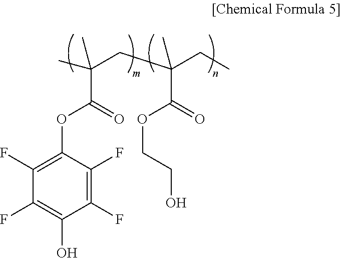

### Example 6: Synthesis Example of Compound Represented by Chemical Formula 6

A compound represented by the following Chemical Formula 6 was synthesized in the same manner as in Example 1, except that 2,3,5,6-tetrafluoro-4-hydroxyphenyl methacrylate (17.70 g) was used instead of 3-fluoro-4-hydroxyphenyl methacrylate (17.15 g), hydroxyethyl methacrylate was used in an amount of 2.30 g instead of 2.85 g, and dimethyl 2,2′-azobis(2-methylpropionate) was used in an amount of 1.63 g instead of 2.01 g.

As identified through ¹H-NMR, the molar ratio (m:n) between respective repeating units in the compound represented by the following Chemical Formula 6 was 80:20.

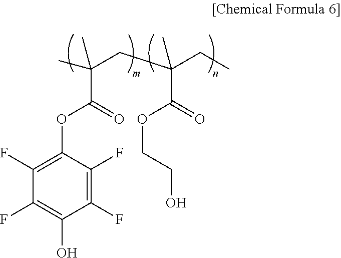

### Example 7: Synthesis Example of Compound Represented by Chemical Formula 7

A compound represented by the following Chemical Formula 7 was synthesized in the same manner as in Example 1, except that 2,3,5,6-tetrafluoro-4-hydroxyphenyl methacrylate (20.00 g) was used instead of 3-fluoro-4-hydroxyphenyl methacrylate (17.15 g), dimethyl 2,2′-azobis(2-methylpropionate) was used in an amount of 1.47 g instead of 2.01 g, and hydroxyethyl methacrylate (2.85 g) was not used.

As identified through ¹H-NMR, the molar ratio (m) of the compound represented by the following Chemical Formula 7 was 100.

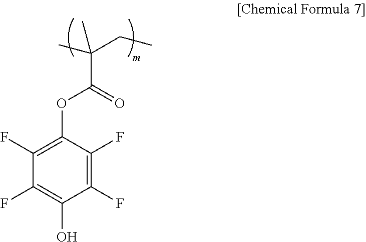

### Example 8: Synthesis Example of Compound Represented by Chemical Formula 8

A compound represented by the following Chemical Formula 8 was synthesized in the same manner as in Example 1, except that 2,3,5,6-tetrafluoro-4-hydroxyphenyl methacrylate (16.98 g) was used instead of 3-fluoro-4-hydroxyphenyl methacrylate (17.15 g), 4-hydroxyphenyl methacrylate (3.02 g) was used instead of hydroxyethyl methacrylate (2.85 g), and dimethyl 2,2′-azobis(2-methylpropionate) was used in an amount of 1.56 g instead of 2.01 g.

As identified through 1H-NMR, the molar ratio (m:n) between respective repeating units in the compound represented by the following Chemical Formula 8 was 80:20.

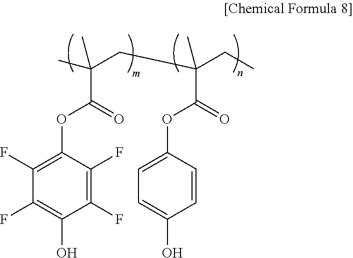

### Example 9: Synthesis Example of Compound Represented by Chemical Formula 9

A compound represented by the following Chemical Formula 9 was synthesized in the same manner as in Example 1, except that 2,3,5,6-tetrafluoro-4-hydroxyphenyl methacrylate (16.18 g) was used instead of 3-fluoro-4-hydroxyphenyl methacrylate (17.15 g), 3-hydroxyadamantan-1-yl methacrylate (3.82 g) was used instead of hydroxyethyl methacrylate (2.85 g), and dimethyl 2,2′-azobis(2-methylpropionate) was used in an amount of 1.49 g instead of 2.01 g.

As identified through 1H-NMR, the molar ratio (m:n) between respective repeating units in the compound represented by the following Chemical Formula 9 was 80:20.

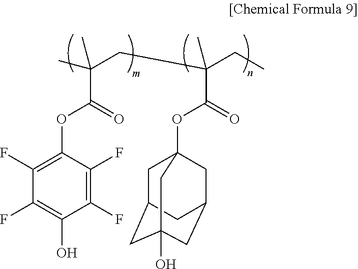

### Comparative Example 1: Compound Represented by Chemical Formula 10

A compound represented by the following Chemical Formula 10 was synthesized using a method described in Preparation Example 4 of Korean Patent Application Laid-Open No. 10-2017-0014120. In the following Chemical Formula 10, n was 5.

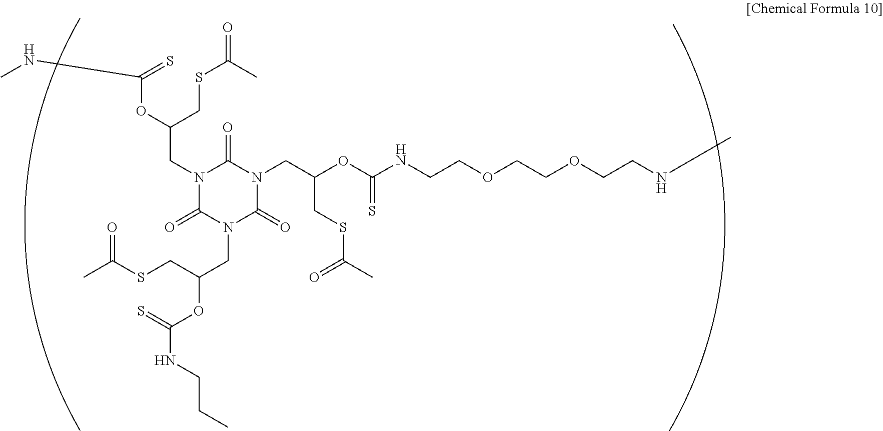

### Comparative Example 2: Synthesis Example of Compound Represented by Chemical Formula 11

A compound represented by the following Chemical Formula 11 was synthesized in the same manner as in Example 1, except that 4-hydroxyphenyl methacrylate (16.91 g) was used instead of 3-fluoro-4-hydroxyphenyl methacrylate (17.15 g), hydroxyethyl methacrylate was used in an amount of 3.09 g instead of 2.85 g, and dimethyl 2,2′-azobis(2-methylpropionate) was used in an amount of 2.19 g instead of 2.01 g.

As identified through 1H-NMR, the molar ratio (m:n) between respective repeating units in the compound represented by the following Chemical Formula 11 was 80:20.

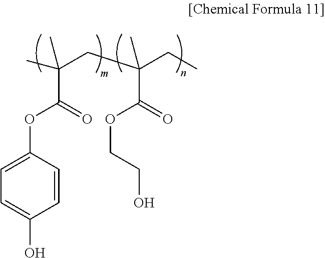

### Comparative Example 3: Synthesis Example of Compound Represented by Chemical Formula 12

A compound represented by the following Chemical Formula 12 was synthesized in the same manner as in Example 1, except that 6-hydroxynaphthyl methacrylate (17.50 g) was used instead of 3-fluoro-4-hydroxyphenyl methacrylate (17.15 g), hydroxyethyl methacrylate was used in an amount of 2.50 g instead of 2.85 g, and dimethyl 2,2′-azobis(2-methylpropionate) was used in an amount of 1.77 g instead of 2.01 g.

As identified through 1H-NMR, the molar ratio (m:n) between respective repeating units in the compound represented by the following Chemical Formula 12 was 80:20.

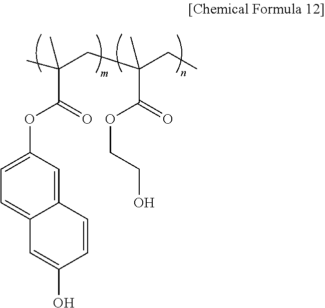

### Comparative Example 4: Synthesis Example of Compound Represented by Chemical Formula 13

A compound represented by the following Chemical Formula 13 was synthesized in the same manner as in Example 1, except that pentafluorophenyl methacrylate (17.71 g) was used instead of 3-fluoro-4-hydroxyphenyl methacrylate (17.15 g), hydroxyethyl methacrylate was used in an amount of 2.29 g instead of 2.85 g, and dimethyl 2,2′-azobis(2-methylpropionate) was used in an amount of 1.62 g instead of 2.01 g.

As identified through 1H-NMR, the molar ratio (m:n) between respective repeating units in the compound represented by Chemical Formula 13 was 80:20.

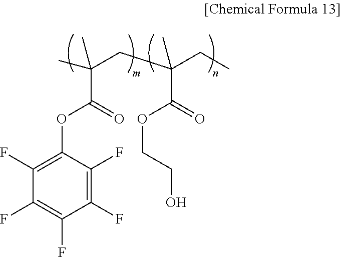

### Preparation Example 1: Preparation of Composition for Forming Resist Underlayer Film

The polymer compound (0.47 g) synthesized using the method according to each of Examples 1 to 9 and Comparative Examples 1 to 4, tetrabutoxymethyl glycoluril (NIKALAC MX-279 of Sanwa Chemical Co., Ltd.) (0.14 g) as a crosslinking agent, triethylammonium nonaflate (0.03 g) as a thermal acid generator, and methyl 2-hydroxyisobutyrate (299.36 g) as a solvent were mixed to prepare a solution. The prepared solution was filtered using a microfilter having a pore diameter of 0.45 μm to prepare a composition for forming a resist underlayer film according to each of Examples 1 to 9 and Comparative Examples 1 to 4.

### Experimental Example: Optimal Exposure Amount and Evaluation of Uniformity of Circular Pattern

For the composition for forming a resist underlayer film prepared using the method according to Preparation Example 1, optimal exposure amount and circular pattern uniformity were evaluated using the following methods.

### 1) Optimal Exposure Amount

The composition for forming a resist underlayer film prepared using the method according to Preparation Example 1 was spin-coated on a silicon wafer, and then baked for 60 seconds at 205° C. to form a resist underlayer film having a thickness of 50 Å.

On the formed resist underlayer film, an EUV resist composition (CAR type positive EUV photoresist) was coated to a thickness of 500 Å, and then soft-baked for 60 seconds at 130° C. Subsequently, the result was exposed with an exposure mask having a hexagonally arrayed hole pattern using EUV exposure equipment (ASML, NXE3300), and then post-baked for 60 seconds at 110° C.

Then, the result was developed with 2.38 wt % of an aqueous tetramethylammonium hydroxide (TMAH) solution to form a hexagonally arrayed hole pattern having a diameter of 26 nm. The resist pattern film formed through the above-described process was observed using a scanning electron microscope, and an optimal exposure amount capable of forming a diameter of 26 nm was identified. In this case, it indicates that productivity and yield were improved as the optimal exposure amount was lower.

### 2) Evaluation of Uniformity of Circular Pattern

Hole circularity, which is uniformity of the circular pattern of 150 holes in the resist pattern film irradiated with energy similar to the optimal exposure amount, was measured using a CG-6300 (Hitachi Group) SEN device. Specifically, the hole circularity is a numerical representation of the degree of circularity of the holes, and uniformity of the circular pattern can be rendered excellent as the value is lower.

TABLE 1

| | | | | | Optimal | |
|---|---|---|---|---|---|---|
| | | Halogen Atom | Hydroxyl Group | m:n | Exposure | |
| | Chemical | of R₁ to R₅ | of R₁ to R₅ | (Molar | Amount | Circularity |
| Classification | Formula | (Substituted) | (Substituted) | Ratio) | (mJ/cm²) | (nm) |
| Example 1 | 1 | Fluorine | ◯ | 80:20 | 74.6 | 1.25 |
| | | (monosubstituted) | (monosubstituted) | | | |
| Example 2 | 2 | Fluorine | ◯ | 80:20 | 75.2. | 1.27 |
| | | (monosubstituted) | (monosubstituted) | | | |
| Example 3 | 3 | Fluorine | ◯ | 80:20 | 75.0 | 1.24 |
| | | (monosubstituted) | (monosubstituted) | | | |
| Example 4 | 4 | Iodine | ◯ | 80:20 | 74.2 | 1.23 |
| | | (monosubstituted) | (monosubstituted) | | | |
| Example 5 | 5 | Fluorine | ◯ | 50:50 | 75.0 | 1.26 |
| | | (tetrasubstituted) | (monosubstituted) | | | |
| Example 6 | 6 | Fluorine | ◯ | 80:20 | 73.1 | 1.27 |
| | | (tetrasubstituted) | (monosubstituted) | | | |
| Example 7 | 7 | Fluorine | ◯ | 100:0 | 71.5 | 1.28 |
| | | (tetrasubstituted) | (monosubstituted) | | | |
| Example 8 | 8 | Fluorine | ◯ | 80:20 | 74.0 | 1.25 |
| | | (tetrasubstituted) | (monosubstituted) | | | |
| Example 9 | 9 | Fluorine | ◯ | 80:20 | 74.2 | 1.26 |
| | | (tetrasubstituted) | (monosubstituted) | | | |
| Comparative | 10 (ref) | X | X | — | 79.8 | 1.21 |
| Example 1 | | | | | | |
| Comparative | 11 | X | ◯ | 80:20 | 78.5 | 1.20 |
| Example 2 | | | (monosubstituted) | | | |
| Comparative | 12 | X | ◯ | 80:20 | 79.5 | 1.23 |
| Example 3 | | | (monosubstituted) | | | |
| Comparative | 13 | Fluorine | X | 80:20 | 81.3 | 1.21 |
| Example 4 | | (pentasubstituted) | | | | |

m:n = mole of repeating unit represented by General Formula 1:mole of repeating unit represented by General Formula 2

Comparing Example 1 and Comparative Examples 2 to 4 in terms of the substituents of the repeating unit represented by General Formula 1 in Table 1, it can be inferred that, when at least one of R₁, R₂, R₃, R₄ and R₅ was a halogen atom and another one was a hydroxyl group in the repeating unit represented by General Formula 1, EUV photon absorption of the resist underlayer film was facilitated by the halogen atom, thereby increasing generation of secondary electrons, and then the generated secondary electrons was able to be smoothly transferred to an upper resist film through the hydroxyl group. Accordingly, an effect similar to a case in which a high exposure amount is irradiated was exhibited. For example, in Comparative Examples 2 and 3, it may be identified that since the repeating unit of General Formula 1 was not substituted with a halogen atom, failing to sufficiently increase the generation of secondary electrons, the optimal exposure amount of the resist film was not sufficiently reduced. In Comparative Example 4 as another example, it may be identified that since the repeating unit represented by General Formula 1 was not substituted with a hydroxyl group, failing to smoothly transfer the generated secondary electrons to an upper resist film, the optimal exposure amount of the resist film was significantly high.

Comparing Examples 5 to 7 in terms of the molar ratio between the repeating unit represented by General Formula 1 and the repeating unit represented by General Formula 2 (General Formula 1:General Formula 2) in Table 1, it may be identified that the optimal exposure amount of the resist film was reduced without affecting the pattern shape of the resist film when the molar ratio was from 80:20 to 100:0.

Comparing Examples 1, 2 and 8 in terms of the number of halogen atoms in Table 1, it may be identified that secondary electrons were sufficiently generated when the number of halogen atoms was 4, reducing the optimal exposure amount of the resist film.

Comparing Examples 1 to 4 in terms of the type of halogen atom in Table 1, it may be identified that secondary electrons were sufficiently generated when the halogen atom was an iodine atom, reducing the optimal exposure amount of the resist film.

Comparing Comparative Example 1 and Examples 1 to 9 in terms of the compound structure in Table 1, the polymer compounds for forming a resist underlayer film prepared using the methods according to Example 1 to 9 included the repeating unit represented by General Formula 1, or additionally further included the repeating unit represented by General Formula 2, thereby increasing a photon absorption rate of the resist underlayer film. As a result, the effect of maintaining the same roughness and size of the resist pattern film even at an exposure amount lower than the optimal exposure amount of the resist film was provided due to the influence of secondary electrons.

Hereinbefore, embodiments of the present disclosure have been described in detail, however, the scope of the present disclosure is not limited thereto, and various modified and improved forms made by those skilled in the art using the basic concept of the present disclosure defined in the claims also fall within the scope of the present disclosure.

What is claimed is:

1. A polymer compound for forming a resist underlayer film, the compound comprising a repeating unit represented by the following General Formula 1: 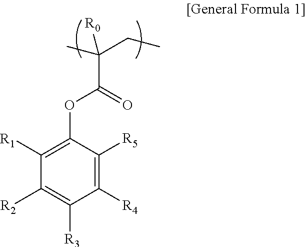
wherein, in General Formula 1,
R₀ is a hydrogen atom, or a linear or branched alkyl group having 1 to 4 carbon atoms;
R₁, R₂, R₃, R₄ and R₅ are each independently a hydrogen atom, a linear or branched alkyl group having 1 to 6 carbon atoms, a halogen atom, or a hydroxyl group; and
at least one of R₁, R₂, R₃, R₄ and R₅ is a halogen atom, and at least another one is a hydroxyl group.

2. The polymer compound of claim 1, wherein four selected from among R₁, R₂, R₃, R₄ and R₅ include a halogen atom.

3. The polymer compound of claim 1, wherein the halogen atom is a fluorine atom or an iodine atom.

4. The polymer compound of claim 1, further comprising a repeating unit derived from an unsaturated compound containing at least one crosslinking reaction functional group at one end.

5. The polymer compound of claim 4, wherein the crosslinking reaction functional group is a hydroxyl group or a thiol group.

6. The polymer compound of claim 4, wherein the unsaturated compound is an acryl-based compound.

7. The polymer compound of claim 1, further comprising a repeating unit represented by the following General Formula 2: 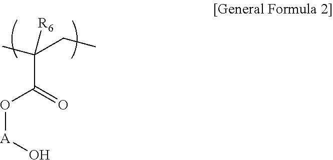
wherein, in General Formula 2,
R₆ is a hydrogen atom, or a linear or branched alkyl group having 1 to 4 carbon atoms; and
A is a substituted or unsubstituted chain-type saturated hydrocarbon linking group having 2 to 12 carbon atoms, a substituted or unsubstituted chain-type unsaturated hydrocarbon linking group having 3 to 12 carbon atoms including at least one unsaturated bond, or a substituted or unsubstituted cyclic linking group having 3 to 12 carbon atoms.

8. The polymer compound of claim 7, wherein the repeating unit represented by General Formula 1 and the repeating unit represented by General Formula 2 have a molar ratio of 50:50 or greater and 100:0 or less.

9. The polymer compound of claim 1, wherein the hydroxyl group and the halogen atom have a ratio of 1:1 to 1:4 in General Formula 1.

10. A composition for forming a resist underlayer film, the composition comprising:
the polymer compound for forming a resist underlayer film of claim 1; and
a solvent.

11. The composition of claim 10, wherein a content of the polymer compound for forming a resist underlayer film is from 0.02% by weight to 1.00% by weight based on a total weight of the composition for forming a resist underlayer film.

12. The composition of claim 10, further comprising at least one of a crosslinking agent or a thermal acid generator.
